(19) United States
(12) Patent Application Publication
(10) Pub. No.: US 2003/0235961 A1
(43) Pub. Date: Dec. 25, 2003

(54) Cyclical sequential deposition of multicomponent films

(75) Inventors: Craig Metzner, Fremont, CA (US); Walter Benjamin Glenn, Pacifica, CA (US)

Correspondence Address: PATENT COUNSEL, APPLIED MATERIALS, INC., Legal Affairs Department, P.O.BOX 450A, Santa Clara, CA, 95052, US

(73) Assignee: APPLIED MATERIALS, INC.

(21) Appl. No.: 10/406,833

(22) Filed: Apr. 4, 2003

Related U.S. Application Data
(60) Provisional application No. 60/373,506, filed on Apr. 17, 2002.

(51) Int. Cl. H01L 21/31; H01L 21/336; H01L 21/469

(52) U.S. Cl. 438/287; 438/785

(57) ABSTRACT

The present invention is directed to depositing multicomponent films with a cyclical sequential deposition (CSD) process. The CSD process deposits a film of a material on a surface by repeating a cycle of process steps comprising sequentially exposing the surface to at least two reactants. The reactants contain precursors that supply the elements that form the multicomponent material. The reactant components that are not precursors may react with the at least one precursor to form a film of the material, or may react with the surface onto which the film of material is to be deposited to prepare the surface for deposition. Each CSD cycle produces a discrete layer of a multicomponent material. The CSD cycle is repeated, depositing one layer each cycle, until the film of multicomponent material reaches the desired thickness.

### CROSS-REFERENCE TO RELATED APPLICATIONS

This application claims benefit of U.S. patent provisional application serial No. 60/373,506 filed Apr. 17, 2002 which is herein incorporated by reference.

### BACKGROUND OF THE INVENTION

1. Field of the Invention

The present invention relates generally to semiconductor device fabrication, and more specifically to the deposition of thin films of materials that are compounds of more than two elements.

2. Description of the Related Art

Throughout its history, the semiconductor industry has realized tremendous gains in productivity and performance by increasing the number of devices that can be incorporated into a single integrated circuit. The increase in the number of devices per integrated circuit is quantified by Moore's law, which states that the number of transistors that can be incorporated into an integrated circuit will double every eighteen months. The industry has increased the number of devices per integrated circuit primarily by device scaling, which is the process of reducing device dimensions while maintaining the electrical properties of the device.

The rate at which the semiconductor industry has been able to scale devices has traditionally been paced by the rate of advances in photolithography. But now, according to the 2001 International Technology Roadmap for Semiconductors (ITRS), device dimensions will soon reach the point at which further reductions will be constrained by the properties of the materials used to fabricate devices. For example, shortcomings in the properties of silicon dioxide (SiO₂), the material that traditionally acts as an insulating layer in semiconductor devices, will soon limit the industry's ability to reduce the size of devices such as transistors and capacitors, and will also limit the industry's ability to place those devices closer together in an integrated circuit.

One of the first devices whose reduction in size will be constrained by the properties of silicon dioxide will be the MOSFET (Metal-Oxide-Semiconductor Field-Effect Transistor). A schematic diagram of a MOSFET is provided in FIG. 1. A MOSFET 10 is fabricated on a semiconductor substrate 20, which is typically a silicon wafer. Just like any transistor, the basic components of a MOSFET are a source, a drain, and a gate that controls the current flowing between the source and the drain. The source and the drain of the MOSFET 10 in FIG. 1 consist of doped regions 21,23 in the substrate 20, while the gate consists of a conductive material 15 separated from the substrate 20 by a gate dielectric 30. A reduction in the size of MOSFET 10 requires a reduction in dimensions such as the gate width 17, the gate length 19, and the gate dielectric thickness 35.

As the dimensions of the MOSFET 10 are reduced in size, the electrical properties of the device must be maintained. The electrical properties of the MOSFET 10 are largely determined by the gate capacitance, which is the capacitance of the capacitor with the gate 15 as one plate, the substrate 20 as the other plate, and with the gate dielectric 30 as the dielectric separating the plates. The capacitance of the gate capacitor is given by

$$C = \frac{{κϵ}_{0} A}{t} ,$$

where κ is the dielectric constant of the gate dielectric material, ε₀ is the permittivity of free space (a constant), A is the area of the capacitor, and t is the thickness of the gate dielectric. In the MOSFET 10 in FIG. 1, the capacitor area A is roughly equal to product of the gate length 19 and the gate width 17. So as the gate length and gate width decrease in size, the area A decreases, resulting in a decrease in the gate capacitance C. In order to maintain the capacitance C within a desired range, which is required to maintain the electrical properties of the MOSFET, either the gate dielectric thickness t must also be decreased or the dielectric constant κ must be increased to compensate for the decrease in A.

For decades, silicon dioxide has been the gate material in MOSFETs. Since the dielectric constant κ of the gate dielectric is determined by the choice of gate dielectric material, previous decreases in gate capacitor area have solely been compensated for by decreasing the thickness of the gate dielectric. According to the ITRS, however, if silicon dioxide continues to be used as the gate dielectric material in MOSFETs, the gate dielectric thickness of future-generations of MOSFETs will become impractically thin. The gate dielectric thicknesses associated with future technology nodes are shown in Table 1.

TABLE 1

| | | Silicon dioxide |
|---|---|---|
| Year | Technology Node | gate thickness tₒₓ (Å) |
| 2001 | 130 nm | 20-28 |
| 2002 | 115 nm | |
| 2003 | 100 nm | 16-24 |
| 2004 | 90 nm | 14-22 |
| 2005 | 80 nm | 12-20 |
| 2006 | 70 nm | 11-18 |
| 2007 | 65 nm | 10-16 |

As the thickness of silicon dioxide gates decrease below around 20 Å, the leakage current through the gate increases to impermissibly high levels. In addition, such extremely thin silicon dioxide gate dielectrics cannot effectively prevent dopants in the gate from diffusing into the underlying substrate. Extremely thin silicon dioxide gate dielectrics also present process difficulties, since such thin layers are difficult to deposit uniformly and reproducibly, and are also more susceptible to damage from subsequent processing steps.

The problems arising from extremely thin silicon dioxide gate dielectrics can be avoided by replacing silicon dioxide with materials having higher dielectric constants. Materials having higher dielectric constants than silicon dioxide are commonly referred to as high-k materials. Replacing silicon dioxide with a high-k material allows the gate dielectric thickness to be increased without changing the gate capacitance. Increasing the thickness of the gate dielectric tends to decrease leakage currents and processing difficulties.

The amount of thickness increase that results from the using a high-k material can be calculated from the formula for capacitance (recited above) by setting the capacitance of a gate capacitor with a silicon dioxide dielectric layer equal to the capacitance of the same gate capacitor with a high-k dielectric layer, and then solving for the thickness of the high-k dielectric layer. The result is the relationship

$${t}_{high - κ} = ( \frac{{κ}_{high - κ}}{{κ}_{ox}} ) {t}_{ox} ,$$

where t_{high-κ} is the thickness of the high-k dielectric layer, tₒₓ is the thickness of the silicon dioxide dielectric layer, κ_{high-κ} is the dielectric constant of the high-k material, and κₒₓ is the dielectric constant of silicon dioxide. This relationship shows that the dielectric layer made up of a high-k material is thicker than an electrically equivalent dielectric layer of silicon dioxide by a factor of (κ_{high-κ}/κₒₓ).

A number of different high-k materials have been considered for use as substitutes for silicon dioxide. Some of the most commonly considered high-k materials are listed in Table 2, along with their respective values of (κ_{high-κ}/κₒₓ).

TABLE 2

| High-k dielectric material | κ | (κ_{high-κ}/κₒₓ) | Morphology |
|---|---|---|---|
| Si₃N₄ | 7 | 1.79 | Amorphous |
| Al₂O₃ | 9 | 2.31 | Amorphous |
| Ta₂O₅ | 26 | 6.67 | Amorphous |
| TiO₂ | 80 | 20.51 | Crystalline |
| HfO₂ | 25 | 6.41 | Crystalline |
| ZrO₂ | 25 | 6.41 | Crystalline |
| (HfO₂)ₓ(SiO₂)₁₋ₓ | Varies with x | Varies with x | Amorphous |
| (ZrO₂)ₓ(SiO₂)₁₋ₓ | Varies with x | Varies with x | Amorphous |

So, for example, replacing the silicon dioxide in the gate dielectric of a MOSFET with HfO₂ would produce an equivalent gate capacitance with an over six-times thicker gate dielectric.

Although the identity of a number of high-k materials is known, the semiconductor industry has not yet substituted these materials for silicon dioxide because of difficulties in processing and integrating those materials. The high-k materials that may be closest to being adopted are silicon oxynitrides (SiOₓN_{y}) and laminates of silicon dioxide (SiO₂) and silicon nitride (Si₃N₄). Just like silicon dioxide, silicon nitride has been widely used in the semiconductor industry for many years. Consequently, it should be relatively easy to develop processes for and to integrate these materials into existing structures. It has found that it is undesirable to have pure silicon nitride contact the substrate, so the portion of a gate dielectric incorporating silicon nitride or a silicon oxynitride must contain an interface layer consisting of either pure silicon dioxide or a silicon oxynidride composition containing oxygen. Accordingly, all proposed silicon oxynitride gate structures consist of either a graded alloy of silicon oxynitride, with the amount of nitrogen increasing with increasing distance from the substrate, or laminated layers of silicon dioxide and silicon nitride, with the silicon dioxide layer contacting the substrate. Consequently, the maximum possible (κ_{high-κ}/κₒₓ) cannot be achieved, so the actual (κ_{high-κ}/κₒₓ) value of silicon oxynitride gate dielectrics lies somewhere between 1 and 1.79. The relatively low (κ_{high-κ}/κₒₓ) of silicon nitride dielectrics means that they only present a short-term solution. In other words, as can be seen in the thickness projections in Table 1, even gate dielectrics using silicon oxynitride materials may have to be less than 20 Å thick by the year 2007. At such thicknesses, even silicon oxynitride dielectrics will likely be subject to leakage and processing problems.

Since silicon oxynitride dielectrics present at best a short-term solution, there has been interest in developing processes for higher-k materials such as metal oxides. Oxides of metals such as aluminum, tantalum, titanium, hafnium, and zirconium have been identified as possibilities for gate dielectrics. Unfortunately, it has been difficult to integrate these oxides into device structures. For example, it has been found that the interface between many of these oxides and silicon tends to be unstable. In particular, reactions between these oxides and silicon tend to occur, changing the properties of the interface and possibly effecting device performance and creating reliability issues. Consequently, it has been proposed to create an interfacial layer of silicon dioxide, silicon oxynitride, or other medium-k material between these high-k materials and the silicon substrate. The addition of the silicon oxide or medium-k layer negates much of the increase in capacitance expected from the use of the metal oxide.

Silicates are stoichiometric or non-stoichiometric mixtures of a metal oxide and silicon dioxide. Silicates containing the metal oxides HfO₂ and ZrO₂ are the primary candidates for use as gate dielectrics since silicates containing Ta₂O₅ or TiO₂ are thermodynamically unstable. By varying the composition of these silicates it is possible to combine the desirable properties of the metal oxide, such as high-k, with the desirable properties of silicon oxide, such as interface stability and an amorphous morphology. The presence of the silicon dioxide in the silicate, however, does result in the overall dielectric constant of the silicate being lower that that of the pure high-k metal oxide component of the silicate. Nevertheless, the combination of silicon dioxide and high-k metal oxide of either hafnium or zirconium produces an amorphous film that is stable on silicon, has a relatively high dielectric constant, and exhibits very low leakage currents.

Although the properties of silicates make them promising high-k candidates, a number of issues must be resolved before silicates can replace silicon dioxide as the gate dielectric material of choice. One issue is that some silicate films have a substantial amount of fixed charge. When a dielectric film has a fixed charge, a voltage must be applied to the device containing the film in order to bring the Fermi level in the dielectric into alignment with the Fermi level of the materials surrounding the dielectric. If the fixed charge in a silicate film is large, or if it is difficult to control the amount of fixed charge incorporated into the film during deposition, then it may not be possible to employ silicate films as gate dielectrics in high-performance MOSFETs.

Another issue regarding the implementation of High k dielectrics is the need for a manufacturable process for depositing those materials. Physical vapor deposition (PVD) is one technique that can been used for depositing high k dielectric films, but concerns over plasma damage, deposition uniformity and lack of conformal coverage over complex topology make this technique less attractive. The inability to manufacturably deposit silicates exemplifies a larger problem affecting the electronics industry: the need to develop manufacturable processes for depositing films of multicomponent materials, which are materials that contain three or more elements. Multicomponent materials are employed in a wide variety of applications in the electronics industry. For example, multicomponent materials such as silicates and BaₓSr₁₋ₓTiO₃ are employed as high-k dielectrics in devices containing transistors and capacitors. Multicomponent materials are also employed in magnetic storage applications, serving as components of thin film heads or of MRAM memory devices. The lack of manufacturable processes for multicomponent films is largely a result of the fact that most existing CVD and ALD deposition chambers are not configured to handle the three or more precursors required to deposit multicomponent films.

### SUMMARY OF THE INVENTION

The present invention is directed to overcoming the aforementioned difficulties associated with depositing multicomponent films, manipulating the properties of multicomponent films, and integrating multicomponent films into device structures.

In one embodiment of the invention, a multicomponent film is deposited using a cyclical sequential deposition (CSD) process. The CSD process deposits a film of a material on a surface by repeating a cycle of process steps comprising sequentially exposing the surface to at least two reactants. The reactants contain precursors that supply the elements that form the multicomponent material. The reactant components that are not precursors may react with the at least one precursor to form a film of the material, or may react with the surface onto which the film of material is to be deposited to prepare the surface for deposition. Each CSD cycle produces a discrete layer of a multicomponent material. The CSD cycle is repeated, depositing one layer each cycle, until the film of multicomponent material reaches the desired thickness.

In a second embodiment of the invention, a CSD process is used to deposit a multicomponent film in which the composition of the film is varied during the course of the CSD process. The variation in composition is accomplished by depositing layers of differing composition. The variation in composition may allow the properties of the overall film to be advantageously modified.

A third embodiment of the invention comprises a deposition system capable of carrying out a CSD process. Such a deposition system might include two or more vaporizers for introducing gaseous reactant that emanate from a liquid sources, in addition to two or more gaseous reactant sources. In some cases it may be advantageous to introduce the various reactants required for formation of the multicomponent film into the reaction chamber through separate inlets, while in other cases it may be advantageous to introduce some or all of the reactants into a pre-mix chamber in order to combine those reactants into a uniform mixture before they're introduced into the reaction chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of a MOSFET.

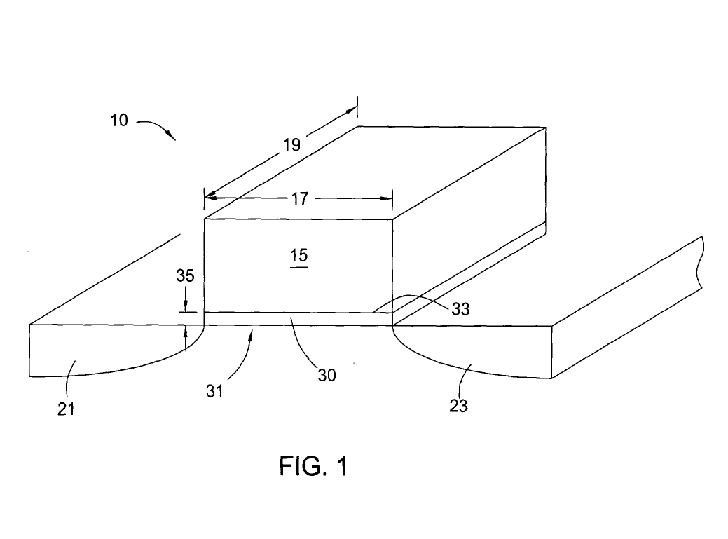

FIG. 2 is reaction chamber capable of carrying out the CSD deposition of a two-component material.

FIG. 3 is a schematic representation of the reactant and carrier gas flows in a CSD process.

FIG. 4 is a cross-section view of the lid of the reaction chamber in FIG. 2.

FIG. 5 is a cross section of a hafnium silicate film deposited by CSD.

FIG. 6 compares the adsorption behavior of reactants in an ALD process and reactants in a CSD process.

FIG. 7 is a cross section of an aluminum-containing hafnium silicate film deposited by CSD.

FIG. 8 is a cross section of a nitrogen-containing hafnium silicate film deposited by CSD.

FIG. 9 is reaction chamber capable of carrying out the CSD deposition of a two-component material.

FIG. 10 is an expanded view of the lid of the reaction chamber in FIG. 9.

FIG. 11 is a cross section of a hafnium silicate film deposited by CSD.

### DETAILED DESCRIPTION OF THE PREFERRED EMBODIMENT

There are a variety of deposition processes that might be used to deposit multicomponent films. The chemical vapor deposition (CVD) process is capable of depositing uniform films over a surface with complex topology. The CVD method consists of exposing the surface to one or more reactants, which include at least one precursor, that react to form a solid thin film on the substrate surface. A reactant, for purposes of this disclosure, is a compound or mixture of compounds that reacts with the surface onto which the film of material is deposited. A precursor, for purposes of this disclosure, is a compound that contains at least one component of the material being deposited. CVD does not inherently involve ion bombardment, so it does create the surface damage associated with sputter deposition. Among the challenges in applying CVD to the growth of multicomponent films is the identification of suitable precursors. For example, if CVD were employed to deposit a silicate film, the metal-containing, silicon-containing, and oxygen-containing precursors must not leave behind unwanted impurities in the deposited silicate film, and the combination of those precursors must form a film with the desired composition. Composition control in the CVD deposition of multicomponent films is particularly problematic because interactions between the multiple precursors may limit the range of compositions that can be deposited. For example, under some conditions certain precursor combinations may produce multi-phase films instead of uniform multicomponent films. Also, since the deposition rate and composition of CVD films depend on a variety of variables such as precursor concentrations, flow dynamics, and temperature, controlling the uniformity of thickness and composition of CVD-deposited multicomponent films may be difficult. Adding to these difficulties is the possibility that the precursors may take part in undesired gas phase reactions. These undesired gas phase reactions may lead to the formation of particulates, and may also deplete the seed gases before they can reach all areas of the substrate.

Undesired gas phase reactions between CVD precursors can by avoided by separately and sequentially introducing the precursors into the reaction chamber. One method that employs the separate and sequential introduction of gaseous reactants is the Atomic Layer Deposition (ALD) method, which is described in U.S. Pat. No. 4,058,430. In ALD, the substrate is heated to a temperature such that when a first precursor is introduced into a reaction chamber, it chemisorbs on the substrate surface, forming a monolayer. An exact monolayer can be formed because the first layer of the precursor is relatively strongly bonded to the surface of the substrate by the chemisorption reaction while any excess precursor is relatively weakly bonded to the chemisorbed monolayer by physisorption. The excess first precursor can consequently be removed from the substrate while leaving the chemisorbed monolayer behind. After the monolayer of the first precursor is formed, excess amounts of the first precursor can be removed from the reaction chamber by, for example, evacuating the reaction chamber with a vacuum pump or by purging the reaction chamber with an inert gas. Next, a second precursor is introduced into the reaction chamber. The second precursor reacts with the monolayer of the first precursor to produce the desired solid thin film. Any excess second precursor, along with any reaction by-products, is then removed from the reaction chamber. Again, the removal may take place by means of evacuating the reaction chamber or purging the reaction chamber with an inert gas. Since the thickness of the film formed by this sequence of steps is limited by the amount of the first precursor that chemisorbs on the substrate, the ALD process is self-limiting. The sequence of steps can be repeated until a thin film of desired thickness is created.

A distinguishing characteristic of the ALD process is that it deposits a precise layer thickness each time the above sequence of steps is repeated. A precise layer thickness is obtained because of the formation of an exact monolayer of the first precursor. This precise layer control resulting from the formation of the monolayer should eliminate the composition and thickness non-uniformities associated with CVD. Non-uniformities in the CVD process largely result from the fact that the deposition rate of CVD-deposited films is a function of reactant concentration and flow conditions. Thus, when a film is being deposited by CVD on the surface of a semiconductor wafer, localized variations in reactant concentrations and flow conditions across the wafer can create thickness non-uniformities. These non-uniformities will not exist in an ALD process as long as all areas of the semiconductor wafer have sufficient exposure to the first precursor so that a monolayer of the precursor can form. Furthermore, since the precursors in ALD are introduced into the reaction chamber separately, instead of simultaneously as in CVD, the number of undesired gas phase reactions between the precursors should be minimized. Furthermore, it has been proposed that it may be possible to vary the composition of a thin film throughout its depth by depositing the film by ALD.

Although ALD eliminates several of the disadvantages of CVD, the constraints of the ALD process limit its applicability. In a classic ALD reaction, the first precursor must chemisorb onto the substrate surface in such a manner that the bond between the substrate and the chemisorbed monolayer of first precursor is significantly stronger than the bond formed between the chemisorbed monolayer and additional first precursor. This difference in bond strength is what gives ALD its characteristic self-limiting deposition. In other words, if the bond between the first precursor and the substrate is not significantly stronger than the bond between the first precursor and itself, then the first precursor will not form an exact monolayer on the substrate. Only a very limited number of precursor/substrate combinations have the required difference in bond strength. Furthermore, the ALD deposition of a particular material on particular substrate materials may be precluded if there is no suitable first precursor for that material that chemisorbs on the substrate material. In other words, there may be no precursor for that certain material that is able to undergo thermodynamically favorable chemisorption reactions on the substrate surface.

For ALD to be applicable to the deposition of a material, not only must there a precursor that bonds with the substrate in a manner that allows self-limiting deposition, but this same precursors must also bond with the material being deposited in a manner that allows self-limiting deposition. For example, if ALD process were to be used to grow a film of SiO₂ on a silicon substrate, the first precursor would have to chemisorb an exact monolayer on the silicon substrate during the first ALD cycle, but in subsequent cycles the first precursor would have to form an exact monolayer on previously formed layers of SiO₂. The requirement that there be a first precursor that undergoes appropriate bonding with both the substrate material and the material being deposited by ALD significantly increases the difficulty of finding precursors that are compatible with the ALD process.

Furthermore, the deposition of a material by the ALD process is precluded if there are no precursors that can react with the substrate and with each other within a “temperature window”. This temperature window is defined by the constraints that the substrate temperature must be high enough for the first precursor to chemisorb on the substrate (or previously ALD deposited layers), high enough for the second precursor to react with the chemisorbed monolayer of the first precursor, but not so high that the monolayer of the precursor either desorbs or thermally decomposes. This temperature window further limits the number of materials that can be deposited with the ALD process.

In the case of depositing multicomponent films such as silicates, there is the additional complication that the multicomponent film contains at least three components. In the case of silicate films these three components are a metal, silicon, and oxygen. ALD processes are typically applied to two component systems where the first precursor contains the first component and the second precursor contains the second component of the film. For example, in the ALD of zirconium oxide the first precursor contains zirconium, while the second precursor contains oxygen. When ALD is applied to three component materials, the first precursor must either contain two components of the film, or the first precursor must comprise two separate precursors each containing a component of the film. When the first precursor comprises two precursors, each precursor must undergo a thermodynamically chemisorption reaction with the substrate, and each precursor must satisfy the “temperature window” requirement. In addition, simultaneously introducing two precursors at once introduces new complications into the process, such as the necessity of controlling the relative amounts of those precursors that chemisorb onto the substrate, and the possibility that those precursors undergo undesired gas phase reactions. These complications make it even more difficult to find suitable precursors for the ALD deposition of multicomponent films.

The CSD process is designed to overcome the shortcomings of existing CVD and ALD processes. The primary difference between a standard CVD process and a CSD process is that in the standard CVD process a film of a material is deposited on a surface by contemporaneously exposing the surface to all of the reactants required for film deposition, while in the CSD process a film of a material is deposited on a surface by sequentially exposing the surface to at least two sub-sets of the reactants. The sequential introduction of subsets of reacts provides CSD with a number of advantages over conventional CVD. One advantage of CSD is that reactants that may undesirably react with each other in the gas phase can be separated from each other, effectively eliminating the undesired reactions. Also, CSD deposits a film of material in a layer-by-layer fashion, with each layer corresponding to the completion of one CSD cycle. This layer-by-layer growth permits the composition of the film being deposited to be changed in each cycle. Accordingly, CSD may be employed to deposit films with varying compositions. When the amount of at least one of the precursors reacting with the surface in a CSD process can be controlled, the thickness of the layer deposited in a cycle may be precisely controlled. The amount of precursor reacting with the surface can be precisely controlled if the adsorption characteristics of the precursor onto the surface are known. The term adsorption, for the purposes of this disclosure, encompasses adhesion of a compound onto the surface by physisorption, chemisorption, chemical reaction, or some combination of these three mechanisms. For example, if the adsorption of a precursor onto the surface is described by the Langmuir adsorption model, then the amount of precursor adsorbed onto the surface can be determined.

The primary difference between a standard ALD process and a CSD process is that in the standard ALD process the first precursor must chemisorb onto the surface in a self-limiting manner, while in a CSD process the first precursor does not necessarily adsorb onto the surface in a self-limiting manner. As disused above, the primary limitation preventing the deposition of multicomponent films by ALD is the difficulty of finding suitable precursors for the deposition of those films. A non-self-limiting CSD process do not require self-limiting chemisorption of a precursor, so such CSD processes are compatible with a much wider range of precursors than are ALD processes. Accordingly, it is much easier to find a set of precursors suitable for the deposition of a multicomponent film by CSD than it is to find a set of precursors suitable for the deposition of a multicomponent film by ALD. As long as the adsorption characteristics of the one or more precursors employed in a CSD are known, that CSD process can deposit a multicomponent film with precise enough layer thickness control to fabricate sub-100 nm technology node devices.

A CSD process suitable for the deposition of silicate films comprises exposing a surface to a first reactant so that a predetermined amount of a first precursor adsorbs onto the surface, and then introducing a second reactant that reacts with the adsorbed first precursor to form the desired film. To control the amount of precursor adsorbed onto the surface, the adsorption characteristics of the precursor on the surface must be determined. After determining these characteristics, the amount of first precursor that adsorbs onto the surface can be controlled by controlling process parameters such as temperature and pressure. After the desired amount of first precursor adsorbs onto the surface, the adsorbed layer of precursor is exposed to a second reactant that reacts with the first precursor to form a layer of material. The CSD cycle is repeated, depositing one layer each cycle, until the film of material reaches the desired thickness.

A CSD process for depositing silicates could be used to deposit a film of hafnium silicate by alternatingly depositing layers of HfO₂ and a SiO₂. The CSD deposition of HfO₂ comprises sequentially exposing a substrate to a hafnium-containing precursor, and then to an oxygen-containing precursor. The CSD deposition of SiO₂ comprises sequentially exposing a substrate to a silicon-containing precursor, and then to an oxygen-containing precursor. The relative number of layers of HfO₂ and SiO₂ in the film determines the overall composition of the hafnium silicate film. Furthermore, by varying the relative number of HfO₂ and SiO₂ layers in the hafnium silicate film during the course of the film deposition, the composition of the film may be varied throughout its depth. Varying the composition of the hafnium silicate film would allow, for example, a more silicon-rich film to be deposited near the gate dielectric-substrate interface so as to provide a more stable interface between the film and the underlying substrate. As the film becomes thicker, increasing the distance from the substrate/dielectric interface, the deposited film may become more hafnium-rich so as to increase the film's dielectric constant.

A CSD process could deposit a film of hafnium aluminum silicate by alternating between the CSD deposition of layers of HfO₂, SiO₂, and Al₂O₃. The composition of the film near the substrate/dielectric interface could be made silicon-rich to provide for a stable interface between the hafnium aluminum silicate film and the substrate. As the thickness of the film increases, however, an increasing number of HfO₂ layers could be deposited in order to increase the dielectric constant of the film. A number of AlO₂ layers are added to the film in order to balance the net fixed charge present in the film. Balancing fixed charges deceases the total amount of fixed charge in the film, and enhances the transistor electrical performance of the dielectric.

A CSD process could deposit a film of a nitrogen containing silicate by alternating between the CSD deposition of layers of HfO₂, SiO₂, and Si₃N₄. The composition of the film near the dielectric/substrate interface would be silicon-rich in order to provide a stable interface. As the thickness of the film increases, an increasing number of HfO₂ layers would be deposited in order to increase the dielectric constant of the film. Layers of Si₃N₄ are also added to the film in order to increase thermal stability of the stack. The silicon nitride in the film increases the crystallization temperature of the whole dielectric stack. It is desirable to maintain amorphous dielectric throughout subsequent high temperature processing commonly found in typical CMOS process flows. The composition near the upper surface of the silicate film would be Si₃N₄ rich to minimize dopant diffusion through the film, and possibly also to provide a stable capping layer on top of the film.

A CSD process could be used to deposit a nitrogen-containing silicate material that contains a metallic element, Si, O, and N. The metallic element could be Zr, Hf, or Al. The film composition may be varied between the different CSD-deposited layers, allowing the film composition to vary continuously throughout the growth of the film. Accordingly, a nitrogen-containing silicate film grown by CSD could consist of layers of Zr₃N₄, Hf₃N₄, Si₃N₄, ZrO₂, HfO₂, and SiO₂.

A CSD process can also be used to deposit multicomponent films that comprise layers of multicomponent compounds. For example, a CSD process may be used to deposit a silicate film consisting of layers of HfₓSiO₂ₓ₊₂. The CSD process for growing a layer of HfₓSiO₂₊₂ would comprise the exposing the surface onto which the layer is to be grown to a first reactant comprising a mixture of at least two precursors: a hafnium-containing precursor and a silicon-containing precursor. The second reactant in the CSD process would oxidize the two precursors. Supplying two precursors in the first reactant in a CSD process allows for the layer-by-layer deposition of multicomponent compounds such as silicates. The composition of the various layers of multicomponent compounds can be varied by changing the relative amounts of the two precursors in the first reactant. For example, by varying the relative amounts of a hafnium-containing precursor and a silicon-containing precursor in the first reactant, the compositions of CSD-deposited hafnium silicate layers may be varied throughout the deposition of a silicate film. So, the portion of the hafnium silicate film near the dielectric/substrate interface could be made silicon-rich to provide a more stable interface with the underlying substrate. And, as the thickness of the film increased, the amount of hafnium in the film could be increased in order to increase the dielectric constant of the film.

A CSD process may be used to deposit a nitrogen containing silicate film on a surface by exposing the surface to a first reactant comprising a mixture of a hafnium-containing precursor and a silicon-containing precursor, and then exposing the surface to either an oxygen-containing precursor or a nitrogen-containing precursor. By varying the relative amounts of the hafnium-containing precursor and the silicon-containing precursor in the first mixture, and by alternating between the oxygen-containing precursor and the nitrogen-containing precursor, the composition of the nitrogen-containing hafnium silicate film may be varied. Near the substrate/dielectric interface, the film would be silicon-rich and low in nitrogen. As the thickness of the film increased, more hafnium would be incorporated into the film in order to increase the dielectric constant. Nitrogen could be added to the bulk of the film to decrease the diffusion of dopants through the film, or it could be added near the top of the film in order to provide a stable capping layer.

A multicomponent film deposited by a CSD process may have nitrogen introduced into the upper portions of the film by a nitridation process. The introduction of nitrogen into the silicate film may reduce dopant diffusion through the film and may provide a stable capping layer on top of the film.

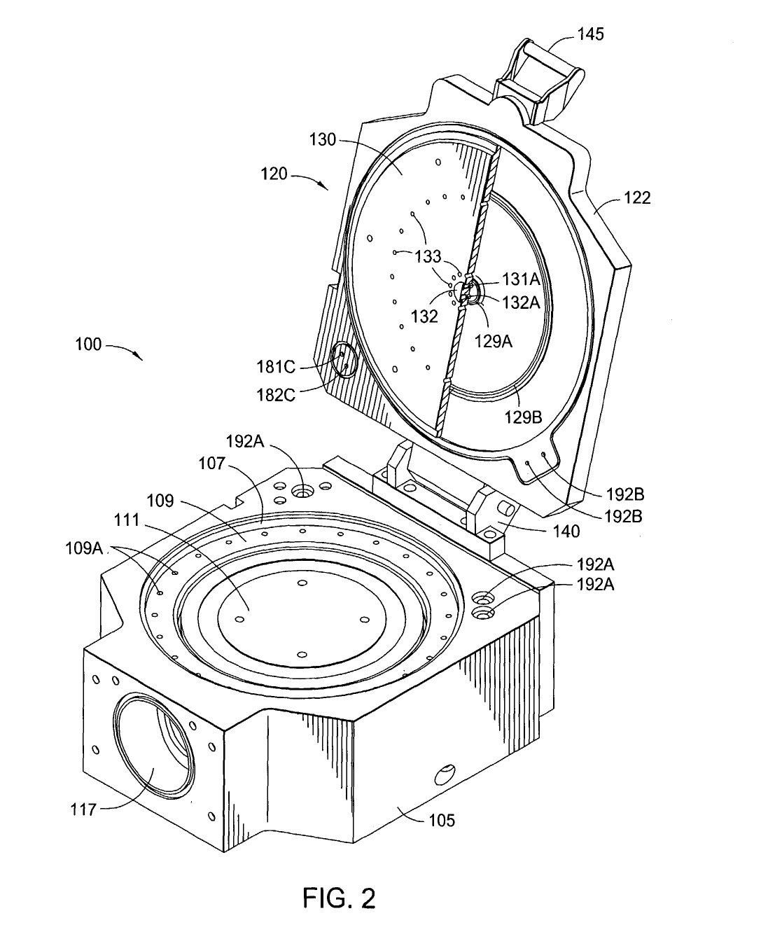

FIG. 2 shows a reaction chamber 100 suitable for carrying out the CSD deposition of a two component films. The features and advantages of reaction chamber 100, are more fully discussed in the co pending application Ser. No. 10/032,293, which is assigned to the assignee of this application and which is hereby incorporated by reference in its entirety. To deposit a two-component film onto a substrate using a CSD process, the substrate (not shown) is first placed on susceptor 111. The chamber lid assembly 120 is then closed, forming a fluid-tight seal with the reaction chamber body 105. Alternatively, the chamber lid assembly 122 may be closed before the wafer is introduced into the interior of the reaction chamber 100 if the reaction chamber 100 contains a load-lock system (not shown) for introducing a wafer into the interior of the reaction chamber 100. In either case, after the wafer is within the sealed reaction chamber, a flow of a carrier gas is introduced into the reaction chamber 100 through apertures 132,133 in the lid 122. It is typically desirable that the carrier gas not participate in the film deposition reactions, so carrier gases are usually relatively inert gases such as argon, helium, hydrogen, nitrogen, or mixtures thereof. After the carrier gas flow begins, the pressure in the reactor is set to a desired level by methods known to those in the art.

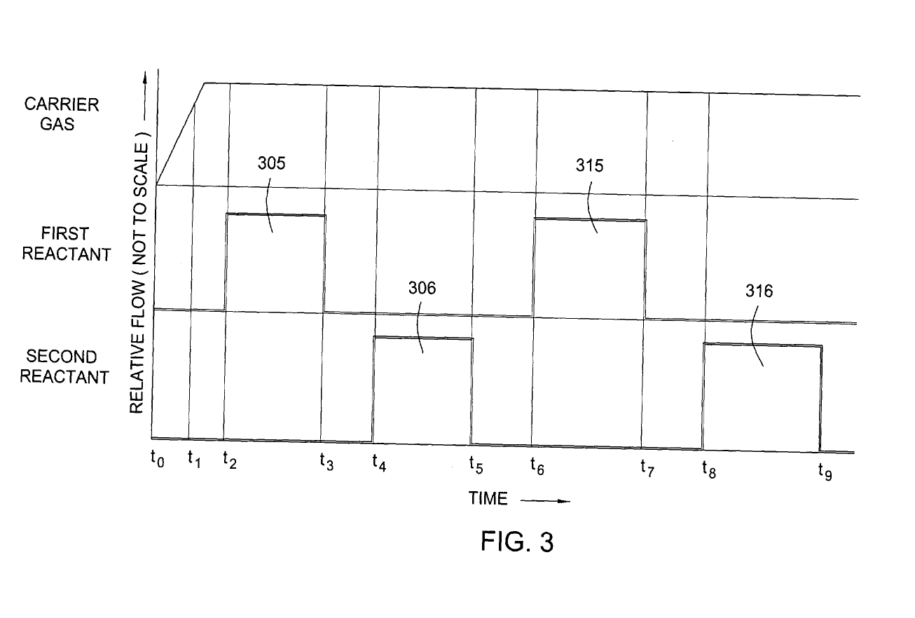

After the pressure in the reactor chamber 100 has equilibrated to the desired level, a CSD cycle is then initiated. The CSD cycle comprises introducing a first reactant into the reaction chamber 100, and subsequently introducing a second reactant into the reaction chamber 100. The relative flows of the various gases into the reaction chamber during a portion of a CSD process are illustrated schematically in FIG. 3. In the embodiment shown in FIG. 3, the flow of carrier gas into the reaction chamber begins at t₀, and reaches the desired level at t₁. In this exemplary embodiment, the flow of carrier gas continues throughout the entire CSD process. The flow is continuous in this embodiment because the two reactants are introduced into the reactor entrained within the flow of carrier gas. In other embodiments, the reactants may not be entrained in a carrier gas, so they would be introduced into the reactor as flows of pure reactant gas.

In the embodiment in FIG. 3, the first reactant gas is introduced into the reaction chamber between times t₂ and t₃. In effect, a pulse of the first reactant gas 305 with a duration of (t₃-t₂) is carried into the reactor by the carrier gas. The duration of the pulse of the first reactant gas 305 is set so that the desired amount of first reactant adsorbs onto the substrate surface. In most cases, the adsorption of the first reactant will not be a self-limiting process, so the amount of first reactant adsorbed onto the substrate will typically continue to increase the longer the duration of the pulse. Thus, the thickness of the layer deposited in a single CSD cycle can be adjusted by adjusting the duration of the pulse of the first reactant.

After the pulse of the first reactant 305 is ended at t₃, a flow of pure carrier gas is introduced into the reactor between t₃ and t₄. The duration of the flow of pure carrier gas must be sufficiently long to spatially separate the pulse of the first reactant 305 from the upcoming pulse of the second reactant 306. In other embodiments, the reactant pulses may be separated from each other by evacuating the reaction chamber with a vacuum pump.

In the embodiment in FIG. 3, the flow of pure carrier gas between times t₃ and t₄ is followed by the introduction into the reaction chamber of a pulse of the second reactant 306. The duration of the pulse of second reactant 306, which in FIG. 3 is t₅-t₄, must be sufficiently long so that enough of the second reactant is introduced into the reaction chamber to completely react with the adsorbed first reactant. Following the pulse of second reactant 306, a flow of pure carrier gas is introduced into the reactor for the period between t₅ and t₆. This flow of pure carrier gas is sufficiently long to spatially separate the pulse of the second reactant 306 from the upcoming pulse of first reactant 315. The process steps occurring between times t₂ and t₆ constitute a single cycle of the CSD process. During this cycle, one layer of material is formed on the substrate. Subsequent cycles are performed until a film of a desired thickness is deposited onto the substrate.

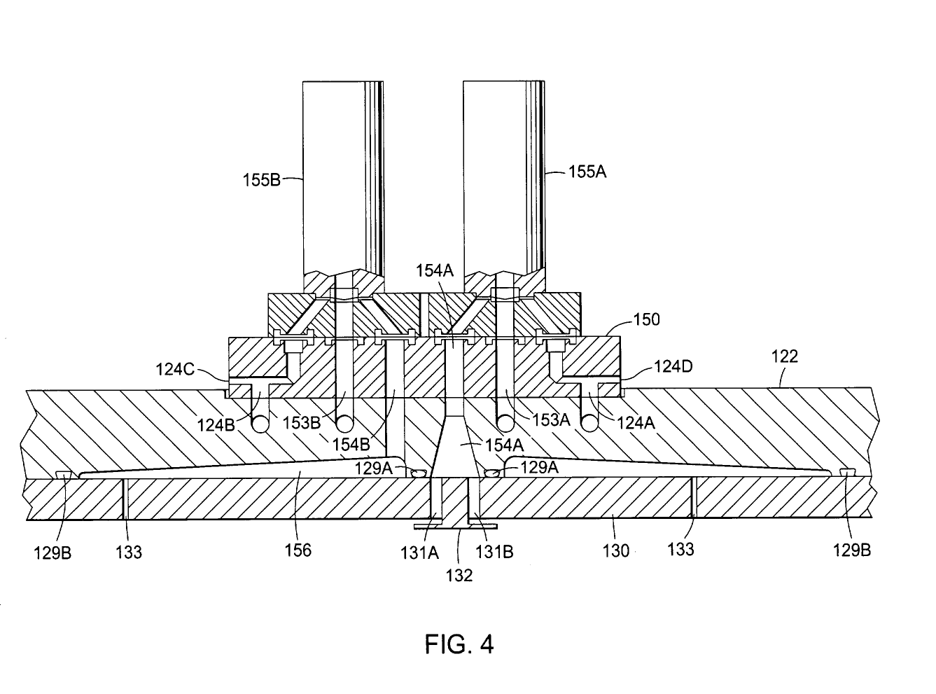

One of the advantages of CSD over CVD is that the sequential introduction of the reactants in CSD prevents the reactants from undergoing unwanted gas phase reactions. Accordingly, a reactor chamber used to carry out a CSD process, such as the reactor chamber 100 in FIG. 2, should be designed to prevent the reactants from being exposed to each other anywhere other than in the immediate vicinity of the substrate. Accordingly, in the reaction chamber 100 in FIG. 2, the first and second reactants are transported from their source containers (not shown) into the reaction chamber 100 through completely separate paths, and are introduced into the reaction chamber 100 through two separate sets of apertures 131A/B, 133. Design features of the reaction chamber pertaining to separating the flows of the first and second reactants are best seen in FIG. 4, which is a cross section of the reactor lid 122 taken along line A-A in FIG. 2. The first reactant, which is entrained in a flow of carrier gas, flows into the lid 122 from its source (not shown) through gas channel 153A. Channel 153A leads to a valve 155A, which can switch between the flow of first reactant and a flow of pure carrier gas that enters the valve 155A through gas channel 124A. The flow exiting the valve, which can be entrained first reactant or pure carrier gas, flows into the reaction chamber though flow channel 154A. The flow through channel 154A enters the reaction chamber through apertures 131A and 131B. The flow exiting apertures 131A and 131B does not directly impinge on the substrate, but is instead directed in a direction parallel to the plane of the substrate surface. Redirecting the flow through channel 154A so that it does not directly impinge on the substrate prevents the flow exiting channel 154A from adversely affecting any deposited or adsorbed layers on the surface of the substrate.

The second reactant flows through the chamber lid 122 in a similar manner. The second reactant, which is entrained in a flow of carrier gas, flows into the lid 122 from its source (not shown) through gas channel 153B. Channel 153B leads to a valve 155B, which can switch between the flow of second reactant and a flow of pure carrier gas that enters the valve 155B through gas channel 124B. The flow exiting the valve, which can be entrained first reactant or pure carrier gas, flows into the reaction chamber though flow channel 154B. The flow through channel 154B enters the reaction chamber through apertures 133. The number of apertures 133 is sufficiently large so that the flow through each aperture is small enough so that the impingement of the flow onto the substrate surface does not adversely affect any deposited or adsorbed layers on the surface of the substrate.

There are a number of features of the reaction chamber in FIGS. 2 and 4 that make the reaction chamber 100 particularly suitable for CSD processes. One of these features is that the valves 155A,155B that direct the reactant flows in to or away from the interior of the reaction chamber 100 are located on the lid 122, which places them in close proximity to the reaction chamber. This close proximity facilitates rapid switching between the two reactants, and between each of the two reactants and the carrier gas, thus allowing the duration of the pulses to be very short. A second feature is that the two reactants are introduced into different zones within the reactant chamber. The first reactant is introduced into the center of the reaction chamber through apertures 131A, 131B, while the second reactant is introduced nearer the periphery of the chamber through apertures 133. Introducing different reactants into different zones of the reactor minimizes the possibility that unwanted gas phase reactions will occur between the reactants.

Since the reaction chamber 100 in FIGS. 2 and 4 only provides for the introduction of two reactants, the chamber can only be used to deposit two-component materials by CSD. Nevertheless, the basic chamber design in FIGS. 2 and 4 may be modified to accommodate the multiple reactants required to deposit mulicomponent films by CSD. One modification would be the introduction of addition channels in the lid for the introduction of additional reactants, and the addition of addition valve to direct the flow of those additional reactants in to or away from the reaction chamber. The advantageous features of the reaction chamber 100 in FIGS. 2 and 4 could be incorporated into a chamber that is able to accommodate the multiple reactants required for multicomponent film deposition. Specifically, the flows of the multiple reactants should be separated until they reach the interior of the reaction chamber, the valves controlling the flow of the multiple reactants should be located as close as possible to the reaction chamber (preferably on the lid of the reaction chamber), and the multiple reactants should be introduced into different zones of the reactor. Each of the reactants is introduced into its respective zone in the reactor through its own set of apertures.

A reaction chamber capable of the CSD deposition of multicomponent films must be connected to sources of the multiple reactants required for the deposition of those films. In general, a reaction chamber capable of depositing multicomponent films by CSD must be connected to at least two vaporizers. For example, a reaction chamber capable of the CSD deposition of silicate films containing hafnium, aluminum, silicon, oxygen, and nitrogen would have to be connected to three vaporizers, and three sources of gas (the third gas being the carrier gas). So flow paths, valves and apertures would have to be provided for five different reactants. For some CSD applications, the reaction chamber may have to be connected to four or more vaporizers, and four or more sources of gas. In addition, it may be advantageous to plasma-activate one for more of the reactant streams before the stream enters the reaction chamber.

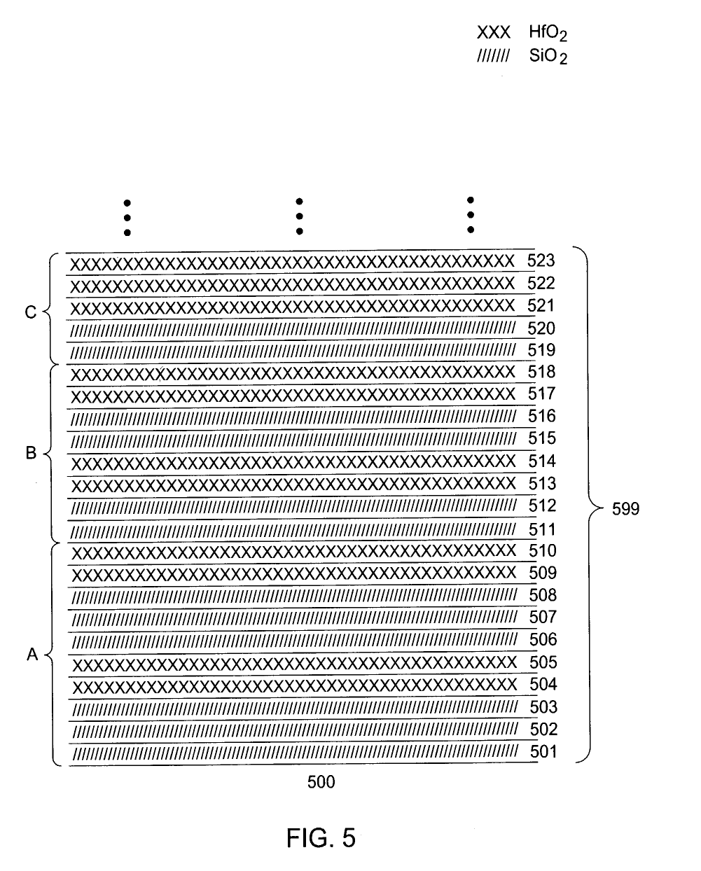

The deposition of a hafnium silicate film that consists of discrete layers of HfO₂ and SiO₂ provides a simple example of a CSD process used to deposit a multicomponent film. FIG. 5 is a cross section of such a hafnium silicate film 599 deposited on a substrate 500. For most applications requiring the deposition of silicates, the substrate material 500 will be silicon. So in order to create as stable an interface as possible between the hafnium silicate film 599 and the silicon substrate 500, the portion 501 of the hafnium silicate film 599 contacting the substrate is SiO₂. This layer of SiO₂ is deposited by a CSD process in which a cycle consists of introducing a silicon-containing reactant into the reaction chamber, introducing pure carrier gas into the reaction chamber, introducing an oxygen-containing reactant into the reaction chamber, and again introducing pure carrier gas into the reaction chamber.

Examples of suitable silicon-containing precursors include silicon-containing coordination compounds. The ligands on the coordination compound could be amino, alkoxyl, siloxyl, β-diketonate, or halide-containing groups. A specific example of a suitable silicon-containing precursor is tri(dimethylamino)silane (TDMAS), which contains three amino groups as ligands. Suitable oxygen-containing precursors are N₂O, H₂O, O₃, O₂, or H₂O₂. A specific example of a suitable oxygen-containing precursor is O₂.

To carry out the CSD process, the pressure in the reaction chamber is adjusted to between about 1 and 10 Torr, preferably to between about 3 and 8 Torr, and most preferably for the TDMAS/O₂ precursor combination to about 5 Torr. The substrate temperature is adjusted to between about 250 and 700° C., preferably to between 325 and 650° C., and most preferably for the TDMAS/O₂ precursor combination to around 485° C. The reactivity of one or both of the precursors may be increased by passing the precursor through a plasma-activated region before it enters the reaction chamber. If, for example, the oxygen-containing precursor is plasma activated, its increased reactivity will permit the substrate temperature to be decrease to temperatures below 250° C. In general, the optimum pressure and temperature for the CSD process for SiO₂ deposition will depend on the exact identity of the silicon-containing and oxygen-containing precursors.

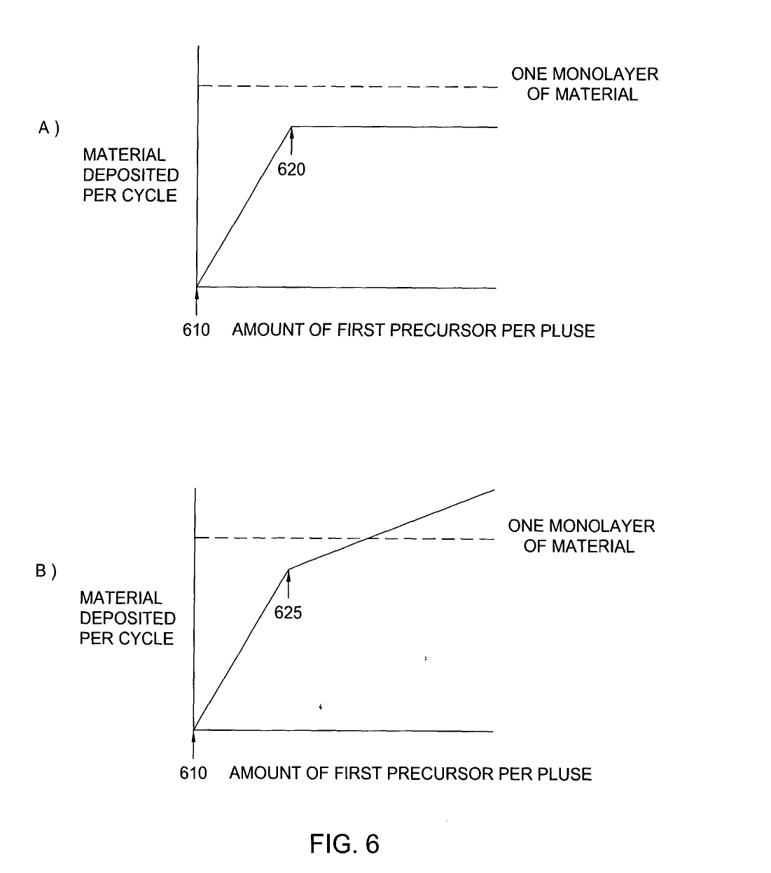

Since the above-described CSD process for the deposition of SiO₂ is not self-limiting, the thickness of a layer deposited by a single cycle will be a function of the duration of the reactant pulse containing the silicon precursor. In general, it is desirable to control the thickness of a layer deposited in a single cycle of an ALD or CSD process by means of controlling the amount of the first precursor available to form the layer of material being deposited. In other words, it is desirable to introduce a sufficient amount of second precursor so that the amount of material that may be deposited is constrained by the availability of the first precursor. FIG. 6 compares the behavior of a self-limiting ALD process with a non-self-limited CSD process, where in both cases the thickness of material is constrained by the availability of the first precursor. The graph in FIG. 6(a) illustrates the dependence of the thickness of a layer deposited in a single ALD cycle on the amount of the first precursor introduced into the reaction chamber. When no first precursor is introduced into the reaction chamber, which corresponds to point 610 on the graph, the layer thickness will be zero. As the amount of first precursor is increased to the amount corresponding to point 620, there is enough of the first reactant to form a chemisorbed monolayer of the first reactant on the substrate. Note that the thickness of the resulting layer is usually less than the ideal monolayer thickness of the material being deposited (the dotted line in FIG. 6(a)) because ligands attached to the first precursor usually create a steric hindrance effect that prevents the first precursor from forming a complete monolayer on the substrate surface. When the amount of the first precursor introduced into the reactor exceeds the amount required to form a monolayer of the precursor on the substrate surface, the excess precursor does not chemisorb onto the substrate surface, so the layer thickness per cycle remains constant at a thickness corresponding to a monolayer of the first precursor. In contrast to ALD, the first precursor in a non-self-limiting CSD process continues to adsorb onto the substrate surface even after sufficient precursor has been introduced into the reactor to form a monolayer. As shown in the graph in FIG. 6(b), the thickness of a layer formed in a cycle continuously increases with increasing amounts of first precursor. In spite of this monotonic increase, there is a knee in the curve at point 625 where the rate of increase in the layer thickness decreases. Accordingly, after the knee at point 625, changes in layer thickness are relatively more insensitive to changes in pulse duration. Accordingly, it is desirable to introduce a sufficient amount of first precursor, which means having a sufficiently long pulse of first precursor, to move the CSD process operating point beyond the knee at point 625.

Although the thickness of a layer of material deposited by CSD depends on the amount of the first precursor introduced into the reactor chamber, while the thickness of a layer of material deposited by ALD is independent of the amount of the first precursor introduced into the reactor chamber (as long as a sufficient amount of the first precursor to form a monolayer has been introduced into the reactor), it is still possible to precisely control the amount of material deposited in a CSD cycle. For a particular set of process parameters, such as pressure and substrate temperature, the curve of FIG. 6(b) will remain constant. In other words, it is possible to precisely control the layer thickness by precisely controlling the dose of first precursor introduced into the reactor. The valve arrangement in the reaction chamber in FIGS. 2 and 4 facilitates precise control over the doses of reactants introduced into the reaction chamber. For the CSD deposition of hafnium silicate films, the valve arrangement allows the pulse duration to be controlled to an accuracy of a few milliseconds. The pulse durations themselves typically fall in the range of 50 ms to 1 s, and most commonly between 300 ms and 500 ms.

Returning to FIG. 5, a film 599 of hafnium silicate is being formed by initially depositing a layer 501 of SiO₂ adjacent to the substrate surface 500 because SiO₂ forms a stable interface with silicon. But since SiO₂ has a much lower dielectric constant than HfO₂, it is desirable to introduce layers of HfO₂ into the film to increase the film's dielectric constant. In order to minimize abrupt changes in film properties, the relative amount of HfO₂ in the film is increased gradually as the film becomes thicker and the distance to the substrate 500 surface increases. Layers of HfO₂ are deposited in a CSD process in which the hafnium-containing precursor may be a hafnium-containing coordination compound in which the ligands are amino, alkoxyl, siloxyl, β-diketonate, or halide-containing groups. Specifically, the hafnium precursor may be the amino-hafnium compound tetrakis-diethylamido-hafnium (TDEAH). Just as in the CSD deposition of SiO₂, the oxygen-containing precursor may be N₂O, H₂O, O₃, O₂, or H₂O₂. The CSD deposition of HfO₂ using these precursors may be carried out in the same pressure and temperature ranges specified above for the CSD deposition of SiO₂.

The amount of HfO₂ in the hafnium silicate film 599 is gradually increased in the hafnium silicate film by gradually decreasing the ratio of SiO₂ layers to HfO₂ layers. Accordingly, as illustrated in FIG. 5, in the portion of the hafnium silicate film adjacent to the substrate 500 surface, which is the portion designated by the letter A, is silicon rich because the ratio of SiO₂ layers to HfO₂ layers is 3:2. In the subsequent portion of the hafnium silicate film, the portion designated by the letter B, the ratio of SiO₂ layers to HfO₂ layers is decreased to 1:1. In the third portion of the hafnium silicate film, the portion designated by the letter C, the ratio of SiO₂ layers to HfO₂ layers is further decreased to 2:3. Portions of the film deposited after portion C may contain successively smaller amounts of SiO₂ so that eventually only layers of pure HfO₂ are being deposited onto the substrate. By gradually decreasing the amount of SiO₂ in this matter, the dielectric constant of the hafnium silicate film may be increased without creating abrupt an abrupt transition between a bulk SiO₂ film and a bulk HfO₂ film.

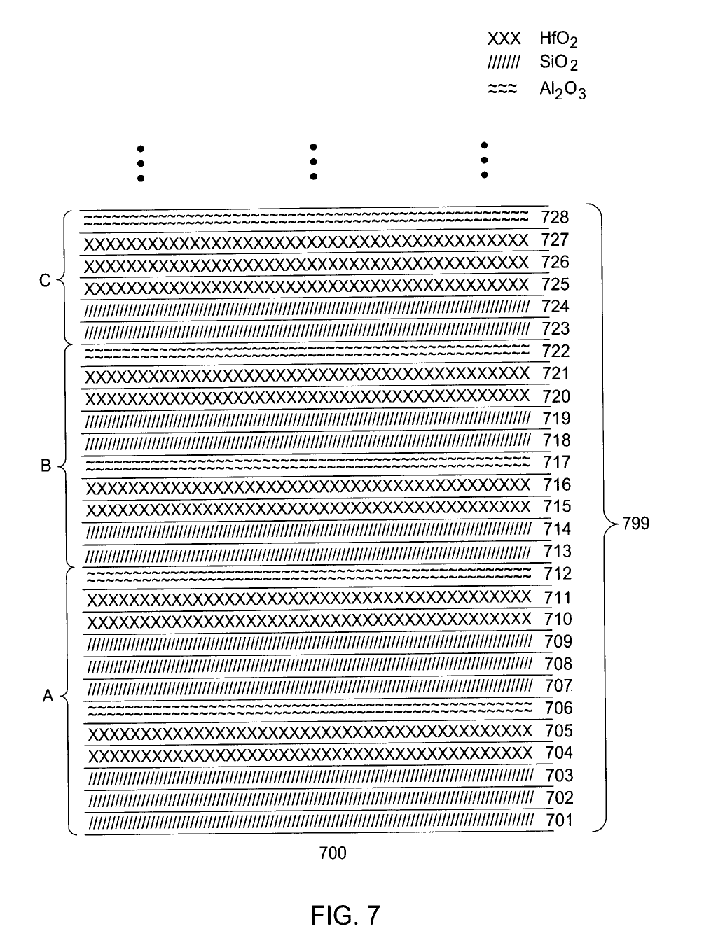

A CSD process may also be used to add aluminum to a silicate film. A silicate film containing aluminum is shown in FIG. 7. The CSD deposition of a aluminum containing silicon film largely parallels the previously described CSD process for depositing hafnium silicate. Thus, just like the hafnium silicate film shown in FIG. 5, the lower portion of the aluminum-containing hafnium silicate film 799 in FIG. 7 is relatively silicon-rich, and the amount of HfO₂ in the film increases with the thickness of the film. The key difference between the films in FIG. 5 and FIG. 7 is the addition of layers of Al₂O₃ 706, 712, 717, 722, 728 in the vicinity of the HfO₂ layers in the film. Since the high-k material HfO₂ is the primary source of fixed charge in the film, it should only be necessary to place Al₂O₃ films that offset the fixed charge in the vicinity of HfO₂ layers. Furthermore, a single layer Al₂O₃ more than negates the charge introduced by a single layer of HfO₂, so it is typically desirable to have fewer Al₂O₃ layers than HfO₂ layers.

The precursor for the introduction of aluminum into a multicomponent film may be a metal organic compound of aluminum such as tri-methyl aluminum. Aluminum precursors suitable for use in CSD processes are disclosed in co-pending patent application serial No. 60/357,382, which is assigned to the assignee of this application, and which is incorporated by reference in its entirety.

For the reasons discussed above, it may be desirable to incorporate nitrogen into a CSD deposited silicate film. One method of incorporating nitrogen into a CSD-deposited film is to have a nitrogen-containing compound be the second reactant in a CSD cycle. So, for example, a CSD-deposited layer of Si₃N₄ may be formed in a CSD cycle comprising the introduction of a first reactant comprising a silicon-containing precursor and a second reactant comprising a nitrogen-containing precursor. Similarly, a CSD-deposited layer of Hf₃N₄ may be formed in a CSD cycle comprising the introduction of a first reactant comprising a hafnium-containing precursor and a second reactant comprising a nitrogen-containing precursor. Examples of compounds that may function as nitrogen-containing precursors in CSD processes include NH₃, N₂, N₂O and NO. The reactivity of any of those nitrogen-containing precursors may be increased by plasma-activating the precursor before it enters the reaction chamber.

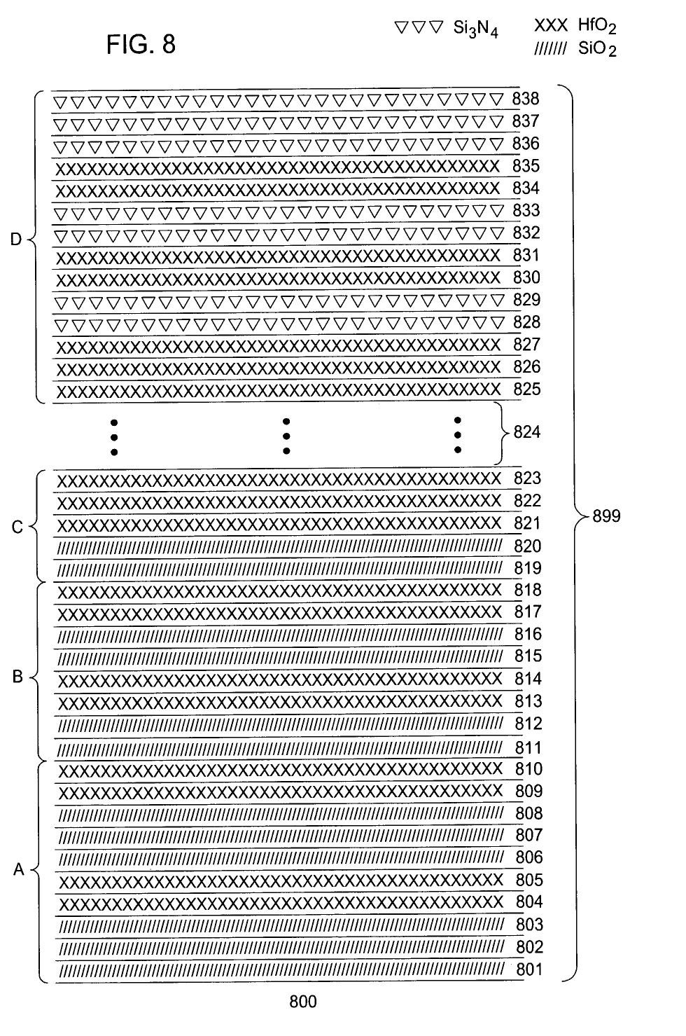

An example of a nitrogen-containing silicate film 899 is shown in FIG. 8. As with the previously discussed silicate films, the film 899 in FIG. 8 is silicon-rich near the substrate 800 surface, and the amount of hafnium in the film increases the film thickness increases. In the film 899 in FIG. 8, layers of Si₃N₄ are present near the top of the film 899. The primary restriction in incorporating nitrogen into a silicate film is that large amounts of nitrogen near the substrate 800 may adversely affect the properties of the interface between the silicate film 899 and the substrate. In addition, the dielectric constant of Si₃N₄ is much lower than the dielectric constant of HfO₂, so it may be desirable to add the minimum amount of Si₃N₄ required to obtain the desired improvements in film properties. Correspondingly, it may be most desirable to incorporate nitrogen into only the top one-third of a silicate film deposited by CSD. Similarly, nitrogen may be incorporated into the top portion of a silicate film by means of any of the industry standard methods for nitridizing a surface, such as baking the silicate film in a nitrogen atmosphere.

In a fifth aspect of the invention, a film of hafnium silicate is deposited by a CSD process comprising sequentially exposing a substrate to a mixture of a hafnium-containing precursor and a silicon-containing precursor, and then exposing the substrate to an oxygen containing precursor in a reactor which is composed not only of a main reaction chamber, but also a pre-mixing chamber. The pre-mixing chamber ensures that the surface on with the film is being grown is exposed to a uniform mixture of the hafnium-containing precursor and silicon-containing precursor.

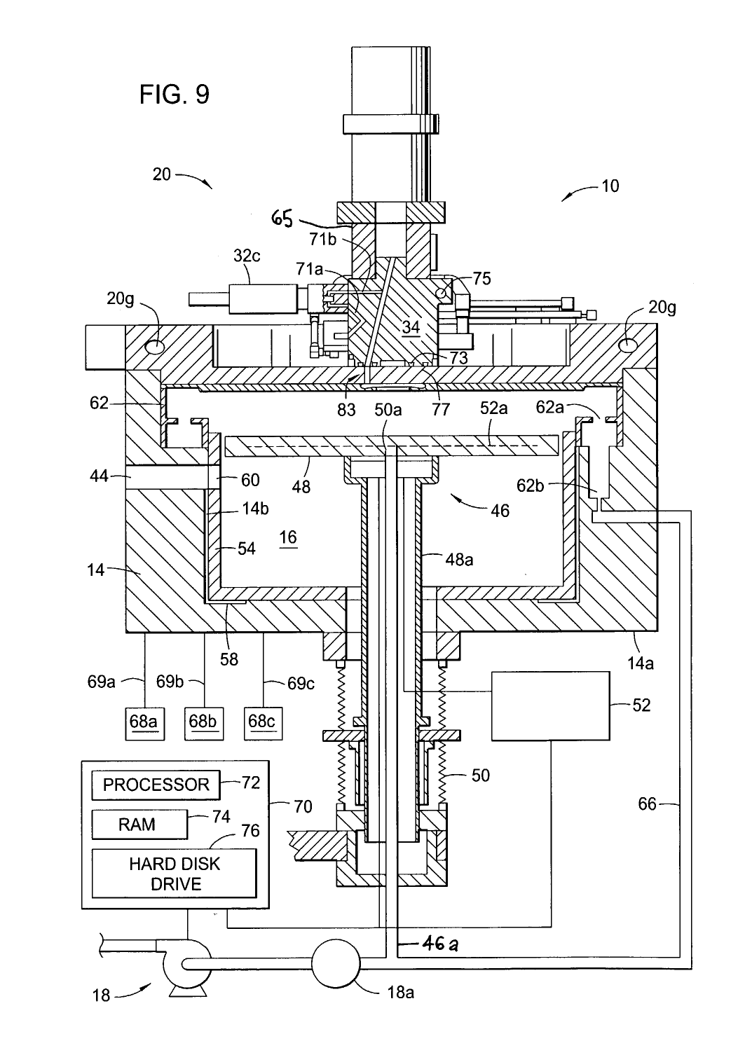

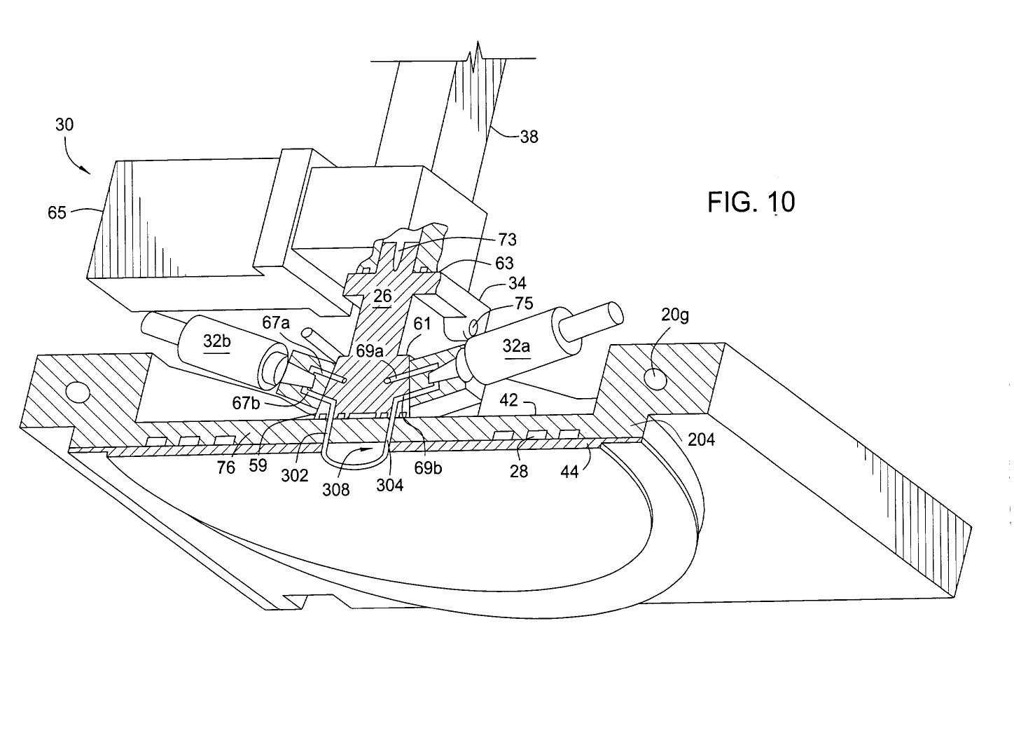

As discussed above, a CSD process can also be used to deposit multicomponent films that comprise layers of multicomponent compounds. For example, a CSD process may be used to deposit a silicate film consisting of layers of HfₓSiO₂ₓ₊₂. A reaction chamber with features that facilitate the growth of multicomponent layers by CSD is shown in FIGS. 9 and 10. This reaction chamber 10 in FIGS. 9 and 10 incorporates some of the advantageous features of the reaction chamber in FIGS. 2 and 4, such as placing the valves 32 controlling precursor flow into the reaction chamber 16 on the chamber lid 83 so that the valves are in close proximity to the reaction chamber 16. In addition, just like the reaction chamber in FIGS. 2 and 4, the reaction chamber 10 in FIGS. 9 and 10 would have to be connected to a least two vaporizers, and more likely three or more vaporizers, in order to be able to deposit multicomponent films by CSD. In addition, the reaction chamber would likely have to be connected to at least two gas sources, and more likely three or four gas sources to be able to deposit multicomponent films by CSD. The feature of reaction chamber 10 that makes it suitable for the CSD deposition of multicomponent layers is the presence of a pre-mixing chamber 308. When a multicomponent layer is deposited by CSD, the first reactant typically comprises a mixture of two precursors. For example, if a film of HfₓSiO₂ₓ₊₂ were to be deposited in a single CSD cycle, the first reactant would include both a hafnium-containing precursor and a silicon-containing precursor. Pre-mixing chamber 308 helps ensure that the first reactant comprises a uniform mixture of the two precursors. Uniformly mixing of the two precursors promotes more uniform deposition of the multicomponent layer. Further features and advantages of the reactor design in FIGS. 9 and 10 are disclosed in co-pending application Ser. No. 10/016,300, which is assigned to the assignee of this application and which is hereby incorporated by reference in its entirety.

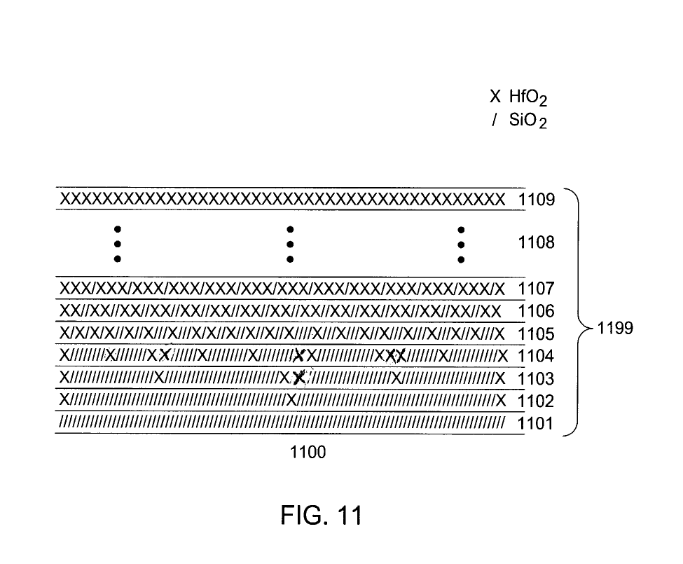

An example of a multicomponent film made up of multicomponent layers is shown in FIG. 11. The layers in the silicate film 1199 in FIG. 11 are layers of HfₓSiO₂ₓ₊₂ of varying composition. For the reasons discussed above, the portions of the silicate film near the substrate 1100 are more silicon-rich, while the amount of hafnium in each layer increases as the layers are further removed from the substrate.

A CSD process used to deposit a multicomponent film may include surface-conditioning steps that facilitate adsorption of the first precursor onto the substrate and onto previously deposited layers. Accordingly, the substrate surface on which the multicomponent film is to be deposited by a CSD process may be conditioned before the CSD process takes place. In addition, some or all of the CSD cycles used to deposit layers of material may include a surface preparation step. For example, a CSD process suitable for the deposition of hafnium silicate films could comprise conditioning the substrate surface to promote adsorption of the first precursor, and then depositing layers of a film by a CSD process comprising adsorbing a predetermined amount of a first precursor onto the surface onto which the film is being grown, introducing a second precursor that reacts with the adsorbed first precursor to form the desired film, and then conditioning the surface of the previously deposited layer to facilitate adsorption of the first precursor in the next CSD cycle. Conditioning the surface of already deposited layers allows the use of precursors that would not otherwise adsorb onto the surface onto which the film is being grown. Surface conditioning steps that treat previously deposited layers could also be added to ALD processes. Accordingly, surface conditioning previously deposited layers in a CSD process or in an ALD process may allow the adsorption of reactants onto surfaces to which they otherwise would not adsorb.

The exact nature of the surface-conditioning step applied to the substrate surface or to the surface of a previously deposited layer would depend on the materials and precursors involved in the CSD or ALD process. For example, in a CSD process in which hafnium silicate is deposited by alternating between the CSD deposition of layers of HfO₂ and a SiO₂, the two oxide layers may be conditioned by terminating the surface of the layers with —OH. This termination may occur, for example, by exposing the surface of a layer to steam generated in an in-situ steam generation system. The —OH termination could also occur by exposing the layer to steam generated by other means, or by exposing the surface to compounds other than water that will hydroxylate the surface. For other material/precursor combinations, it may be desirable to reduce the surface of previously deposited layers by, for example, exposing the surface of the layers to a hydrogen plasma.

It should be noted that although the present invention has been described in terms of a number of specific embodiments, those embodiments are intended to be merely illustrative of the present invention. The spirit and scope of the invention is not limited to those embodiments. It is intended that the present invention be defined solely by the appended claims.

While the foregoing is directed to embodiments of the present invention, other and further embodiments of the invention may be devised without departing from the basic scope thereof, and the scope thereof is determined by the claims that follow.

1. A method for forming a hafnium containing structure on a substrate surface in a process chamber, sequentially comprising:
a) delivering a hafnium precursor to the substrate surface;
b) purging the process chamber with a purge gas;
c) delivering a nitrogen precursor or an oxygen precursor to the substrate surface;
d) purging the process chamber with the purge gas;
e) delivering a silicon precursor to the substrate surface;
f) purging the process chamber with the purge gas;
g) delivering the oxygen precursor or the nitrogen precursor to the substrate surface to form a structure comprising hafnium, nitrogen, oxygen and silicon; and
h) purging the process chamber with the purge gas.

2. The method of claim 1, wherein the hafnium precursor comprises at least one ligand selected from the group consisting of amino, alkoxy, siloxyl, beta-diketonate and halide.

3. The method of claim 1, wherein the silicon precursor comprises at least one ligand selected from the group consisting of amino, alkoxy, siloxyl, beta-diketonate and halide.

4. The method of claim 1, wherein the nitrogen precursor is selected from the group consisting of NH₃, N₂ and plasma activated variants thereof.

5. The method of claim 1, wherein the oxygen precursor is selected from the group consisting of H₂O, H₂O₂, O₃ and O₂.

6. A method for forming a hafnium containing structure on a substrate surface in a process chamber, sequentially comprising:
a) delivering a hafnium precursor to the substrate surface;
b) purging the process chamber with a purge gas;
c) delivering a nitrogen precursor to the substrate surface;
d) purging the process chamber with the purge gas;
e) delivering a silicon precursor to the substrate surface;
f) purging the process chamber with the purge gas;
g) delivering an oxygen precursor to the substrate surface; and
h) purging the process chamber with the purge gas.

7. The method of claim 6, wherein the hafnium precursor comprises at least one ligand selected from the group consisting of amino, alkoxy, siloxyl, beta-diketonate and halide.

8. The method of claim 6, wherein the silicon precursor comprises at least one ligand selected from the group consisting of amino, alkoxy, siloxyl, beta-diketonate and halide.

9. The method of claim 6, wherein the nitrogen precursor is selected from the group consisting of NH₃, N₂ and plasma activated variants thereof.

10. The method of claim 6, wherein the oxygen precursor is selected from the group consisting of H₂O, H₂O₂, O₃ and O₂.

11. A method for forming a hafnium containing silicate compound on a substrate surface in a process chamber, sequentially comprising:
a) delivering a hafnium precursor to the substrate surface;
b) purging the process chamber with a purge gas;
c) delivering an oxygen precursor to the substrate surface;
d) purging the process chamber with the purge gas;
e) delivering a silicon precursor to the substrate surface;
f) purging the process chamber with the purge gas;
g) delivering a nitrogen precursor to the substrate surface; and
h) purging the process chamber with the purge gas.

12. The method of claim 11, wherein the hafnium precursor comprises at least one ligand selected from the group consisting of amino, alkoxy, siloxyl, beta-diketonate and halide.

13. The method of claim 11, wherein the silicon precursor comprises at least one ligand selected from the group consisting of amino, alkoxy, siloxyl, beta-diketonate and halide.

14. The method of claim 11, wherein the nitrogen precursor is selected from the group consisting of NH₃, N₂ and plasma activated variants thereof.

15. The method of claim 11, wherein the oxygen precursor is selected from the group consisting of H₂O, H₂O₂, O₃ and O₂.

16. A method for forming a hafnium-containing compound on a substrate surface in a process chamber, sequentially comprising:
a) delivering a silicon precursor to the substrate surface, wherein the substrate surface comprises hafnium nitride;
b) purging the process chamber with a purge gas;
c) delivering an oxygen precursor to the substrate surface; and
d) purging the process chamber with the purge gas.

17. The method of claim 16, wherein the hafnium nitride is deposited by a cyclical sequential deposition technique.

18. The method of claim 17, wherein the hafnium nitride is deposited from a hafnium precursor comprising at least one ligand selected from the group consisting of amino, alkoxy, siloxyl, beta-diketonate and halide.

19. The method of claim 17, wherein the hafnium nitride is deposited from a nitrogen precursor selected from the group consisting of NH₃, N₂ and plasma activated variants thereof.

20. The method of claim 16, wherein the silicon precursor comprises at least one ligand selected from the group consisting of amino, alkoxy, siloxyl, beta-diketonate and halide.

21. The method of claim 16, wherein the oxygen precursor is selected from the group consisting of H₂O, H₂O₂, O₃ and O₂.

22. A method for forming a metal-containing compound on a substrate in a process chamber, comprising:
depositing a first compound selected from a group consisting of Zr₃N₄, Hf₃N₄, Si₃N₄, ZrO₂, HfO₂ and SiO₂ by cyclical sequential deposition using at least two cycles; and
depositing a second compound selected from the group consisting of Zr₃N₄, Hf₃N₄, Si₃N₄, ZrO₂, HfO₂ and SiO₂ by cyclical sequential deposition using at least two cycles, whereas the second compound is different from the first compound.
